(19) United States
(12) Patent Application Publication
(10) Pub. No.: US 2017/0341938 A1
(43) Pub. Date: Nov. 30, 2017

(54) SYSTEM AND METHOD OF FORMING CARBON NANOTUBES

(71) Applicant: The Boeing Company, Chicago, IL (US)

(72) Inventors: Keith Daniel Humfeld, Federal Way, WA (US); Iti Srivastava, Summerville, SC (US)

(21) Appl. No.: 15/168,333

(22) Filed: May 31, 2016

(51) Int. Cl. C01B 32/16; C23C 16/26; C23C 16/52; C23C 16/455; C23C 16/448; B82Y 40/00; B82Y 30/00

(52) U.S. Cl. CPC C01B 32/16; C23C 16/45593; C23C 16/26; C23C 16/4485; C23C 16/52; B82Y 30/00; B82Y 40/00; Y10S 977/742; Y10S 977/843

(57) ABSTRACT

A chemical vapor deposition (CVD) system for forming carbon nanotubes from solid or liquid feedstock. The system includes a reactor including a housing that includes an inlet and an outlet. The housing defines an interior for receiving the feedstock, and the interior receives inert gas. The CVD system includes a first stop valve in flow communication with the inlet and a second stop valve in flow communication with the outlet. The first and second stop valves seal the inlet and the outlet such that a static environment is formed in the interior when reacting the feedstock. A heater heats the interior to a temperature such that the feedstock is vaporized, thereby forming vaporized feedstock. The CVD system further includes a controller coupled in communication with the first and second valves and the heater. The controller is configured to selectively actuate the first and second valves and the heater.

### BACKGROUND

The field of the present disclosure relates generally to nanotube technology and, more particularly, to systems and methods of forming carbon nanotubes in a static environment with a fixed quantity of solid or liquid feedstock.

Carbon nanotubes are small tube-shaped structures fabricated essentially from single-atom thick sheets of graphene in tubular form. Generally, carbon nanotubes can be classified as either single-wall or multi-wall carbon nanotubes. Single-wall carbon nanotubes have only one cylindrical graphitic layer, and multi-wall carbon nanotubes have two or more nested cylindrical graphitic layers. Carbon nanotubes generally have a diameter less than about 100 nanometers and large aspect ratios such that a length of the nanotube is significantly greater than its diameter. For example, the length to diameter ratio of carbon nanotubes may be greater than about 1000 to 1. Moreover, carbon nanotubes have been shown to exhibit high strength, unique electrical properties, and to be efficient conductors of heat. Such features make carbon nanotubes advantageous for use in a variety of mechanical, electrical, and/or thermal applications.

Carbon nanotubes are typically fabricated using a chemical vapor deposition process. More specifically, a gaseous hydrocarbon feedstock (e.g., acetylene) is mixed with a carrier gas (e.g., a mixture of hydrogen and argon). The mixture is then pre-heated and channeled into a tube furnace reactor containing a carbon nanotube growth catalyst, wherein the mixture is heated to a temperature sufficient to grow carbon nanotubes. Growth times for carbon nanotubes fabricated in this manner can be between about 60 minutes and about 80 minutes, and the mixture is continuously channeled through the tube furnace reactor during the growth period. However, typically less than one percent of the carbon atoms in the feedstock are utilized in the fabrication of the carbon nanotubes, with the remainder being discharged from the tube furnace reactor as waste. As such, large amounts of material are required to fabricate carbon nanotubes of a predetermined length. Moreover, the energy costs associated with heating the mixture channeled through the tube furnace reactor is directly proportionate to the amount of material required to fabricate the carbon nanotubes.

### BRIEF DESCRIPTION

In one aspect, a chemical vapor deposition (CVD) system for use in forming carbon nanotubes from solid or liquid feedstock is provided. The system includes a reactor including a housing that includes an inlet and at least one outlet. The housing defines an interior configured to receive the solid or liquid feedstock, and the interior is sized to receive a predetermined amount of inert gas. The CVD system further includes a first stop valve coupled in flow communication with the inlet and a second stop valve coupled in flow communication with the at least one outlet. The first stop valve and the second stop valve are configured to seal the inlet and the at least one outlet such that a static environment is formed in the interior when reacting the solid or liquid feedstock. A heater is configured to heat the interior to a temperature such that the solid or liquid feedstock is vaporized, thereby forming vaporized feedstock. The CVD system further includes a controller coupled in communication with the first stop valve, the second stop valve, and the heater. The controller is configured to selectively actuate the first stop valve, the second stop valve, and the heater for controlling operation of the chemical vapor deposition system.

In another aspect, a reactor for use in forming carbon nanotubes from solid or liquid feedstock is provided. The reactor includes a housing that includes an interior configured to receive the solid or liquid feedstock, an inlet, and at least one outlet. The inlet and the at least one outlet are sealable such that a static environment is formed in the interior when reacting the solid or liquid feedstock. The reactor also includes a door configured to provide access to the interior.

In yet another aspect, a method of forming carbon nanotubes from solid or liquid feedstock within a reactor is provided. The method includes filling the reactor with a predetermined amount of inert gas, sealing the reactor such that a static environment is formed within the reactor, and heating the reactor to a temperature such that the solid or liquid feedstock is vaporized, thereby forming vaporized feedstock.

### BRIEF DESCRIPTION OF THE DRAWINGS

FIG. 1 is a schematic illustration of an exemplary chemical vapor deposition system;

FIG. 2 is a schematic illustration of an exemplary reactor that may be used with the chemical vapor deposition system shown in FIG. 1, the reactor shown in baseline configuration;

FIG. 3 is a schematic illustration of the reactor shown in FIG. 2 in a first operational mode;

FIG. 4 is a schematic illustration of the reactor shown in FIG. 2 in a second operational mode;

FIG. 5 is a schematic illustration of the reactor shown in FIG. 2 in a third operational mode; and

FIG. 6 is a flow diagram illustrating an exemplary method of forming carbon nanotubes.

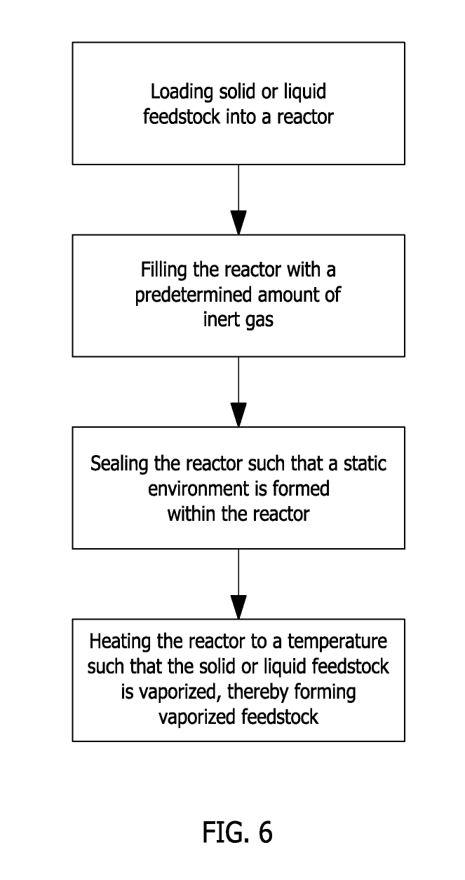

### DETAILED DESCRIPTION

The implementations described herein relate to systems and methods of forming carbon nanotubes in a static environment with a fixed quantity of solid or liquid feedstock. In the exemplary implementation, the system includes a tube furnace reactor that is sealable for forming the static environment such that only the materials contained within the reactor at sealing are used to form the carbon nanotubes. For example, the reactor receives the feedstock and the growth catalyst, and is then filled with inert gas, sealed, and heated towards growth temperature. The feedstock vaporizes when heated such that the vaporized feedstock is capable of reacting with the growth catalyst to form the carbon nanotubes. Hydrocarbons in the vaporized feedstock remain in the reactor until utilized, until neutralized, or until the end of the growth cycle. As such, forming the carbon nanotubes in the static environment facilitates increasing the utilization rate of carbon atoms in the feedstock, thereby decreasing the amount of feedstock required to grow a particular sample of carbon nanotubes. Moreover, energy use is reduced when compared to typical continuous feed chemical vapor deposition processes. For example, continuous feed chemical vapor deposition processes include a feedstock line for channeling gaseous feedstock to the reactor. The system described herein eliminates the feedstock line, thereby eliminating the need to insulate the line and preheat the contents of the line.

As used herein, “static environment” refers to a closed environment that does not exchange mass with a surrounding environment when reactor 102 is sealed.

As used herein, an element or step recited in the singular and proceeded with the word “a” or “an” should be understood as not excluding plural elements or steps, unless such exclusion is explicitly recited. Furthermore, references to “exemplary implementation” or “one implementation” of the present disclosure are not intended to be interpreted as excluding the existence of additional implementations that also incorporate the recited features.

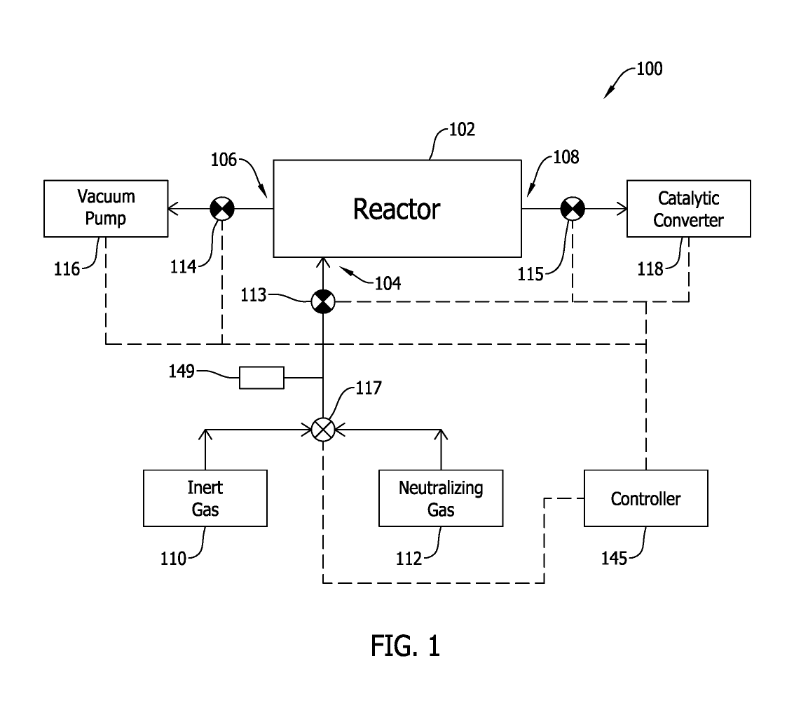

FIG. 1 is a schematic illustration of an exemplary chemical vapor deposition (CVD) system 100. In the exemplary implementation, CVD system 100 includes a reactor 102 including an inlet 104 and at least one outlet. More specifically, in the illustrated embodiment, reactor 102 includes a first outlet 106 and a second outlet 108. CVD system 100 also includes a source 110 of inert gas and a source 112 of neutralizing gas coupled in communication with inlet 104. As will be described in more detail below, source 110 of inert gas channels inert gas towards reactor 102 and source 112 of neutralizing gas channels neutralizing gas towards reactor 102 at different stages of the chemical vapor deposition growth process. An exemplary inert gas includes, but is not limited to, a mixture of hydrogen and argon. An exemplary neutralizing gas contains nitrogen and oxygen, such as, but not limited to, air.

Moreover, as will be described in more detail below, inlet 104, first outlet 106, and second outlet 108 are sealable such that a static environment is formed in reactor 102. For example, in one implementation, CVD system 100 includes a plurality of stop valves for sealing inlet 104, first outlet 106, and second outlet 108. More specifically, a first stop valve 113 is coupled at inlet 104, a second stop valve 114 is coupled at first outlet 106, and a third stop valve 115 is coupled at second outlet 108. In the exemplary implementation, valves 113, 114, and 115 are two-position valves (e.g, valves that can be either opened or closed). In addition, a three-way valve 117 is coupled between inlet 104 and sources 110 and 112.

CVD system 100 also includes a vacuum pump 116 coupled in communication with first outlet 106, and a catalytic converter 118 coupled in communication with second outlet 108. Vacuum pump 116 is selectively operable to reduce a pressure within an interior of reactor 102 when sealed. Reducing the pressure within reactor 102 reduces an amount of inert gas required for fabrication of carbon nanotubes, and also reduces the amount of energy required for heating reactor 102 to a predetermined growth temperature. For example, it takes less energy to heat the reduced mass of material contained within reactor 102 when vacuum pump 116 is operable. Moreover, as will be described in more detail below, catalytic converter 118 receives gas discharged from reactor 102 and reduces potentially harmful emissions in the gas before exhausting it to the environment.

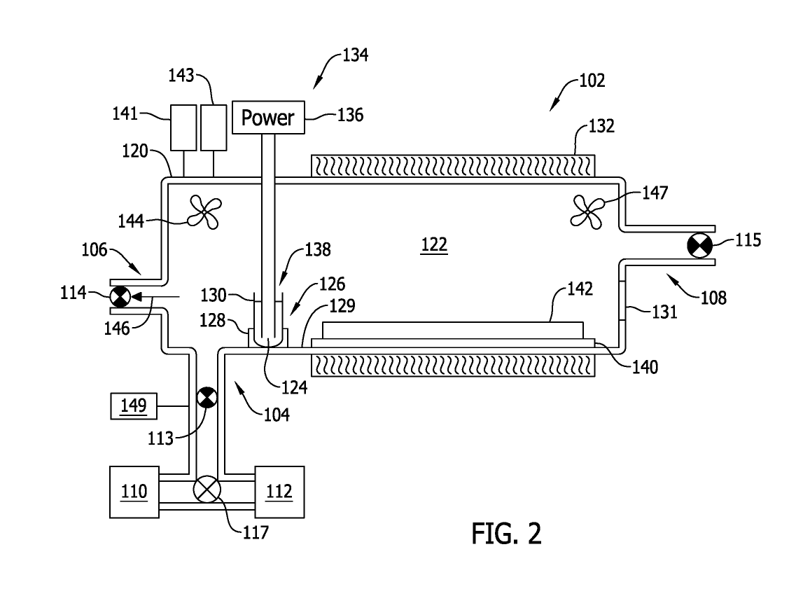

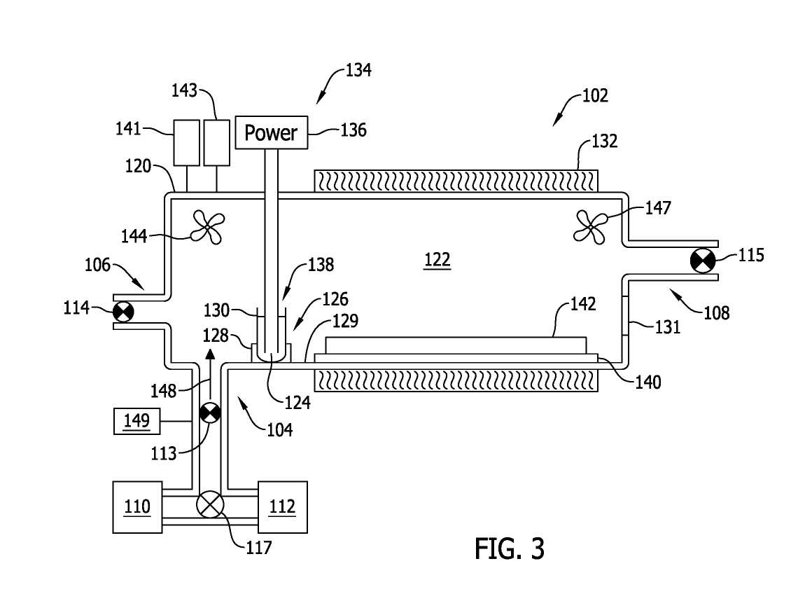

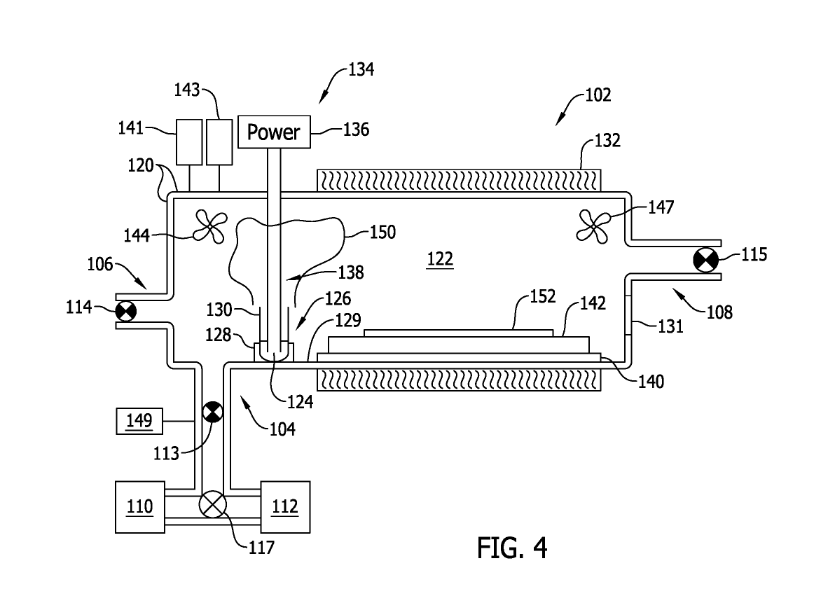

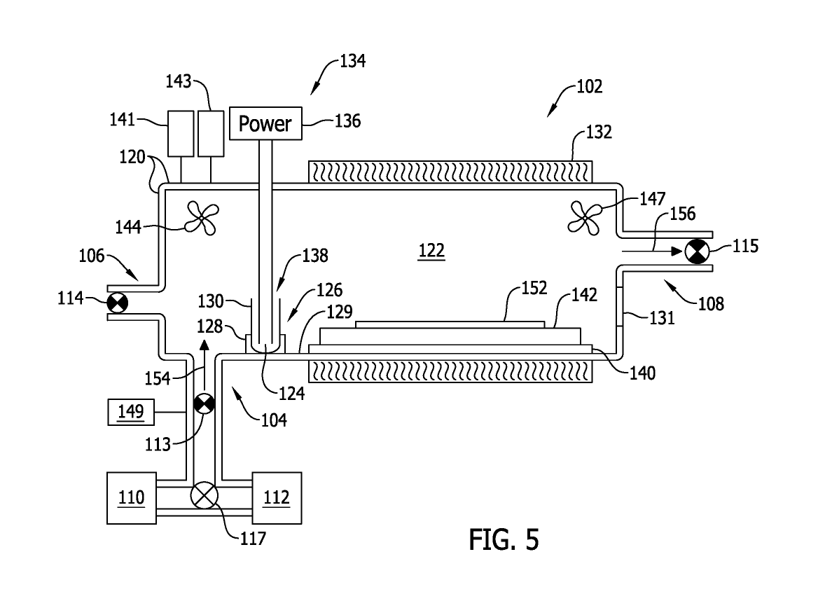

FIG. 2 is a schematic illustration of reactor 102 that may be used with chemical vapor deposition system 100 (shown in FIG. 1), reactor 102 is shown in a baseline configuration, FIG. 3 is a schematic illustration of reactor 102 in a first operational mode, FIG. 4 is a schematic illustration of reactor 102 in a second operational mode, and FIG. 5 is a schematic illustration of reactor 102 in a third operational mode. In the exemplary implementation, reactor 102 includes a housing 120 including an interior 122 for receiving solid or liquid feedstock 124. Moreover, inlet 104, first outlet 106, and second outlet 108 are sealable such that a static environment is formed in interior 122 when reacting solid or liquid feedstock 124.

Any solid or liquid feedstock may be used in reactor 102 that enables CVD system 100 to function as described herein. For example, at standard temperature and pressure, exemplary liquid feedstock includes, but is not limited to, octane and decane. Moreover, at standard temperature and pressure, exemplary solid feedstock includes, but is not limited to, isocane and triacontane.

In one implementation, a feedstock holder 126 for receiving solid or liquid feedstock 124 is positioned within interior 122. More specifically, feedstock holder 126 includes a mounting base 128 coupled to an interior surface 129 of housing 120, and a removable receptacle 130 selectively coupled to mounting base 128. Removable receptacle 130 is for receiving solid or liquid feedstock 124 and mounting base 128 is configured to ensure removable receptacle 130 remains in a substantially upright or vertical position during operation of reactor 102. As such, removable receptacle 130 is capable of being removed and replaced within reactor 102 for easily replenishing solid or liquid feedstock 124 within interior 122 between growth cycles. Reactor 102 also includes a door 131 for providing access to interior 122 to enable a user to position the feedstock within reactor 102. In an alternative implementation, feedstock holder 126 is a one-piece or unitary device.

In the exemplary implementation, a heater 132 is coupled to reactor 102. As shown, heater 132 is thermally coupled to housing 120, and heats interior 122 by conducting heat to housing 120, which then heats interior 122 through convection. In one embodiment, heater 132 is an electric heater. Heater 132 facilitates heating interior 122 of reactor 102 to a predetermined growth temperature defined within a range between about 800° C. and about 900° C. As will be described in more detail below, interior 122 is heated to the predetermined growth temperature such that solid or liquid feedstock 124 is vaporized, thereby forming vaporized feedstock. As such, the vaporized feedstock fills interior 122 for reaction with a growth catalyst to form carbon nanotubes.

In some implementations, an electrical discharge device 134 is coupled to feedstock holder 126. Electrical discharge device 134 includes a power source 136 and a pair of electrodes 138 coupled to power source 136. When energized by power source 136, an electrical discharge (not shown) is formed between the pair of electrodes 138. The pair of electrodes 138 are positioned within removable receptacle 130 for embedding within solid or liquid feedstock 124 such that the electrical discharge formed between the pair of electrodes 138 facilitates vaporization of solid or liquid feedstock 124. In operation, the electrical discharge creates a localized temperature increase that converts solid or liquid feedstock 124 positioned between the pair of electrodes 138 to smaller chain hydrocarbons. The smaller chain hydrocarbons vaporize more readily as a temperature within interior 122 is increased towards the predetermined growth temperature. As such, the evaporation rate of solid or liquid feedstock 124 is increased, and chemical cracking of solid or liquid feedstock 124 is reduced.

Reactor 102 also includes a quartz tube 140 and a substrate 142 positioned within interior 122. Substrate 142 is positioned over quartz tube 140 and is fabricated from silicon, for example. Moreover, substrate 142 includes a layer of growth catalyst (not shown) positioned thereon for reacting with vaporized feedstock. Exemplary materials used to fabricate the growth catalyst include, but are not limited to, aluminum, molybdenum, and iron.

In the exemplary implementation, reactor 102 further includes a temperature sensor 141, a pressure sensor 143, and a pair of circulating devices 144 and 147 coupled within interior 122. Temperature sensor 141 and pressure sensor 143 monitor a temperature and a pressure within interior 122, and periodically or continuously provides temperature and pressure feedback data to a controller 145 for use in controlling the chemical vapor deposition process. As will be described in more detail below, circulating devices 144 and 147 provide turbulence within interior 122 such that vaporized feedstock is circulated throughout interior 122, and such that inert gas within interior is mixed with the vaporized feedstock. As such, a substantially uniform distribution of vaporized feedstock is formed within interior 122 to ensure the vaporized feedstock contacts the growth catalyst. Exemplary circulating devices 144 and 147 include, but are not limited to, an electric fan.

CVD system 100 further includes controller 145 (shown in FIG. 1) for automatically controlling operation of CVD system 100. Controller 145 includes a memory and a processor, comprising hardware and software, coupled to the memory for executing programmed instructions. The processor may include one or more processing units (e.g., in a multi-core configuration) and/or include a cryptographic accelerator (not shown). Controller 145 is programmable to perform one or more operations described herein by programming the memory and/or processor. For example, the processor may be programmed by encoding an operation as executable instructions and providing the executable instructions in the memory.

The processor may include, but is not limited to, a general purpose central processing unit (CPU), a microcontroller, a reduced instruction set computer (RISC) processor, an open media application platform (OMAP), an application specific integrated circuit (ASIC), a programmable logic circuit (PLC), and/or any other circuit or processor capable of executing the functions described herein. The methods described herein may be encoded as executable instructions embodied in a computer-readable medium including, without limitation, a storage device and/or a memory device. Such instructions, when executed by the processor, cause the processor to perform at least a portion of the functions described herein. The above examples are exemplary only, and thus are not intended to limit in any way the definition and/or meaning of the term processor.

The memory is one or more devices that enable information such as executable instructions and/or other data to be stored and retrieved. The memory may include one or more computer-readable media, such as, without limitation, dynamic random access memory (DRAM), synchronous dynamic random access memory (SDRAM), static random access memory (SRAM), a solid state disk, and/or a hard disk. The memory may be configured to store, without limitation, executable instructions, operating systems, applications, resources, installation scripts and/or any other type of data suitable for use with the methods and systems described herein.

Instructions for operating systems and applications are located in a functional form on non-transitory memory for execution by the processor to perform one or more of the processes described herein. These instructions in the different implementations may be embodied on different physical or tangible computer-readable media, such as a computer-readable media (not shown), which may include, without limitation, a flash drive and/or thumb drive. Further, instructions may be located in a functional form on non-transitory computer-readable media, which may include, without limitation, smart-media (SM) memory, compact flash (CF) memory, secure digital (SD) memory, memory stick (MS) memory, multimedia card (MMC) memory, embedded-multimedia card (e-MMC), and micro-drive memory. The computer-readable media may be selectively insertable and/or removable from controller 145 to permit access and/or execution by the processor. In an alternative implementation, the computer-readable media is not removable.

Controller 145 is coupled, either by wired or wirelessly connectivity, in communication with one or more of stop valves 113, 114, and 115, three-way valve 117, vacuum pump 116, catalytic converter 118 (each shown in FIG. 1), heater 132, electrical discharge device 134, temperature sensor 141, pressure sensor 143, and circulating devices 144 and 147. In one implementation, controller 145 is autonomous when controlling the devices listed above during the carbon nanotube growth process. Alternatively, controller 145 is partially autonomous such that controller 145 can receive commands or other inputs from an operator during the carbon nanotube growth process.

Initially, CVD system 100 and reactor 102 are set to a baseline configuration as shown in FIG. 1. In the baseline configuration, valves 113, 114, and 115, and door 131 are closed. Vacuum pump 116, heater 132, and circulating devices 144 and 147 are also off or deactivated. To begin the process, door 131 is opened and removable receptacle 130 containing solid or liquid feedstock 124 is loaded into reactor 102. In one embodiment, receptacle 130 is manually loaded into reactor 102 by an operator and door 131 is subsequently closed.

Referring to FIG. 2, showing CVD system 100 and reactor 102 in the first operational mode (i.e., the purging mode), wherein interior 122 is purged of air and filled with inert gas. To purge interior 122 of air, controller 145 receives a start command from the operator and commands stop valve 114 into an open position. To control actuation of valve 114, and also valves 113, 115, and 117, controller 145 sends commands to the valves to open or close a specific valve. More specifically, controller 145 outputs the voltages and/or currents necessary to actuate valves 113, 114, 115, and 117 in accordance with the commands from controller 145. Controller 145 actuates the other devices, such as vacuum pump 116, catalytic converter 118, heater 132, electrical discharge device 134, and circulating devices 144 and 147, in a similar manner.

Once valve 114 has been opened, controller 145 actuates vacuum pump 116 (shown in FIG. 1) to draw a stream 146 of air from within interior 122 through first outlet 106 to reduce a pressure within interior 122. In the exemplary implementation, vacuum pump 116 is activated until a pressure within interior 122 is within a range between about 0.5 atmospheres (atm) and about 1.0 atm.

Controller 145 determines when interior 122 reaches a predetermined pressure, such as between about 0.5 atm and about 1.0 atm. In the exemplary embodiment, controller 145 determines the pressure within interior 122 either based on a runtime of vacuum pump 116 or based on pressure feedback data received from pressure sensor 143. When interior 122 reaches the predetermined pressure, controller 145 commands valve 114 to close.

In the second operational mode, shown in FIG. 3, interior 122 is filled with inert gas. More specifically, controller 145 commands stop valve 113 to open from a closed position and commands three-way valve 117 into a position such that a stream 148 of inert gas is channeled through inlet 104 from source 110. Stream 148 of inert gas is channeled into interior 122 at a rate and for a period of time such that reactor 102 is filled with a predetermined amount of inert gas. In the illustrated embodiment, a flow meter 149 is coupled between inlet 104 and sources 110 and 112. As such, in one implementation, controller 145 receives feedback from flow meter 149 and determines a time required to channel stream 148 through inlet 104 based on a known volume of interior 122. Alternatively, the predetermined amount of inert gas is determined based on an interior pressure within interior 122 and based on feedback received from pressure sensor 143.

Reactor 102 is then sealed such that a static environment is formed within reactor 102, as shown in FIG. 1. To seal reactor 102, controller 145 commands stop valve 113 closed to seal interior 122. In an alternative implementation, reactor 102 is operated at an internal pressure greater than about 1.0 atm to ensure any leaks in reactor 102 causes outward discharge relative to interior 122 so as to not disturb the growth process.

Referring to FIG. 4 showing CVD system 100 and reactor 102 in the third operational mode, wherein CVD system 100 is configured to grow nanotubes. In the third operational mode, once reactor 102 is sealed, controller 145 (shown in FIG. 1) actuates heater 132 to heat reactor 102 to a predetermined growth temperature such that solid or liquid feedstock 124 is vaporized, thereby forming vaporized feedstock 150. For example, the predetermined growth temperature is selected to be high enough to vaporize solid or liquid feedstock 124. Controller 145 actuates heater 132 after the close command for valve 113 is transmitted. Moreover, controller 145 monitors temperature sensor 141 and pressure sensor 143, and controls operation of heater 132 based on temperature feedback data received from temperature sensor 141. More specifically, controller 145 uses the temperature feedback data from temperature sensor 141 to control operation of heater 132 and ensure interior 122 is maintained at the predetermined growth temperature.

In one implementation, controller 145 also actuates electrical discharge device 134 to facilitate vaporizing solid or liquid feedstock 124 before the temperature within reactor 102 reaches the predetermined growth temperature. Electrical discharge device 134 is actuated before the temperature within reactor 102 reaches the predetermined growth temperature to convert solid or liquid feedstock 124 positioned between the pair of electrodes 138 to smaller chain hydrocarbons that vaporize at a lower temperature than solid or liquid feedstock 124. As such, vaporized hydrocarbons are present within interior 122 at temperatures less than the predetermined growth temperature.

Moreover, controller 145 actuates circulating devices 144 and 147 to circulate vaporized feedstock 150 throughout reactor 102 such that vaporized feedstock 150 mixes with the inert gas within interior 122. In one implementation, actuation of circulating devices 144 and 147 is based on actuation of heater 132 (i.e., circulating devices 144 and 147 are actuated when heater 132 is operating). Alternatively, circulating devices 144 and 147 are actuated based on temperature feedback data from temperature sensor 141. For example, in one implementation, controller actuates circulating devices 144 and 147 when a temperature within reactor 102 is greater than a predetermined threshold. Circulating devices 144 and 147 facilitate circulating vaporized feedstock 150 within interior 122 such that the hydrocarbons of vaporized feedstock 150 are substantially uniformly distributed throughout the inert gas for reacting with the growth catalyst on substrate 142. The hydrocarbons are consumed when reacted with the growth catalyst, thereby reducing the concentration of vaporized hydrocarbons in interior 122 and forming carbon nanotubes 152 on substrate 142.

Referring to FIG. 5 showing CVD system 100 and reactor 102 in the fourth operational mode, wherein excess hydrocarbons are vented from reactor 102. In operation, once the growth of carbon nanotubes 152 is substantially completed, the concentration of excess hydrocarbons within interior 122 is controlled (i.e., reduced) in a neutralizing process. In one implementation, controller 145 determines when the concentration of feedstock in interior 122 is reduced to below the threshold level and when to perform the neutralizing process based on a preset amount of time that has passed since starting the nanotube growth process. In one implementation, controller 145 determines the preset amount of time from the start time actuation of heater 132.

In the neutralizing process, and after the preset time has elapsed, controller 45 (shown in FIG. 1) turns off heater 132. Controller 145 commands stop valve 113 to open from the closed position to unseal inlet 104. Controller 145 also commands three-way valve 117 into a position such that a stream 154 of neutralizing gas is channeled into interior 122 through inlet 104 from source 112 of neutralizing gas. The neutralizing gas facilitates neutralizing unreacted hydrocarbons of vaporized feedstock 150. More specifically, the nitrogen and oxygen-containing neutralizing gas reacts with the hydrocarbons to produce carbon dioxide and other organic molecules that do not participate in the growth of carbon nanotubes 152. As such, the growth reaction is terminated, and the low-temperature neutralizing gas facilitates rapidly cooling interior 122 in preparation of receiving additional solid or liquid feedstock for use in a subsequent growth cycle. Controller 145 then commands stop valve 115 to open such that a stream 156 of neutralized gas is discharged through second outlet 108 from within interior 122. Stream 156 is channeled through catalytic converter 118 (shown in FIG. 1) for reducing potentially harmful emissions in the neutralized gas before exhausting it to the environment.

While described in the context of automatic operation with controller 145, it should be understood that one or more steps of the carbon nanotube growth process may be conducted manually.

A method of forming carbon nanotubes 152 from solid or liquid feedstock within reactor 102 is also described herein. The method includes filling reactor 102 with a predetermined amount of inert gas, sealing reactor 102 such that a static environment is formed within reactor 102, and heating reactor 102 to a temperature such that solid or liquid feedstock 124 is vaporized, thereby forming vaporized feedstock 150. The method further includes circulating vaporized feedstock 150 throughout reactor 102 such that vaporized feedstock 150 mixes with the inert gas. In one implementation, circulating vaporized feedstock 150 includes actuating at least one circulating device 144 or 147 when the temperature within reactor 102 is greater than a predetermined threshold.

The method further includes forming an electrical discharge across a pair of electrodes 138 positioned such that the electrical discharge facilitates vaporization of solid or liquid feedstock 124. Moreover, the method includes channeling a stream 154 of neutralizing gas into reactor 102 after carbon nanotubes 152 have been formed, wherein the neutralizing gas neutralizes unreacted hydrocarbons of vaporized feedstock 150.

In addition, in one implementation, heating reactor 102 includes heating reactor 102 to the temperature defined within a range between about 800° C. and about 900° C. Moreover, filling reactor 102 with a predetermined amount of inert gas includes reducing a pressure within reactor 102 to a predetermined pressure, and filling reactor 102 with the inert gas when a pressure within reactor 102 reaches the predetermined pressure.

This written description uses examples to disclose various implementations, including the best mode, and also to enable any person skilled in the art to practice the various implementations, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A chemical vapor deposition (CVD) system for use in forming carbon nanotubes from solid or liquid feedstock, said system comprising:
a reactor comprising:
a housing that comprises an inlet and at least one outlet, said housing defining an interior configured to receive the solid or liquid feedstock, said interior sized to receive a predetermined amount of inert gas;
a first stop valve coupled in flow communication with said inlet;
a second stop valve coupled in flow communication with said at least one outlet, wherein said first stop valve and said second stop valve are configured to seal said inlet and said at least one outlet such that a static environment is formed in said interior when reacting the solid or liquid feedstock; and
a heater configured to heat said interior to a temperature such that the solid or liquid feedstock is vaporized, thereby forming vaporized feedstock; and
a controller coupled in communication with said first stop valve, said second stop valve, and said heater, said controller configured to selectively actuate said first stop valve, said second stop valve, and said heater for controlling operation of the chemical vapor deposition system.

2. The system in accordance with claim 1 further comprising a circulating device coupled within said interior, said circulating device configured to mix the inert gas with the vaporized feedstock.

3. The system in accordance with claim 1, wherein said reactor further comprises a door configured to provide access to said interior.

4. The system in accordance with claim 1 further comprising a vacuum pump coupled in communication with said at least one outlet, said vacuum pump configured to reduce a pressure within said interior when sealed.

5. The system in accordance with claim 1 further comprising a feedstock holder positioned within said interior, said feedstock holder configured to receive the solid or liquid feedstock.

6. The system in accordance with claim 5, wherein said feedstock holder comprises:
a mounting base coupled within said interior; and
a removable receptacle selectively coupled to said mounting base, said removable receptacle configured to receive the solid or liquid feedstock.

7. The system in accordance with claim 5 further comprising an electrical discharge device coupled to said feedstock holder, said electrical discharge device comprising a pair of electrodes positioned such that an electrical discharge formed between said pair of electrodes facilitates vaporization of the solid or liquid feedstock.

8. The system in accordance with claim 1 further comprising a catalytic converter coupled in communication with said at least one outlet, said catalytic converter configured to receive a stream of the neutralized gas from within said interior.

9. A reactor for use in forming carbon nanotubes from solid or liquid feedstock, said reactor comprising:
a housing that comprises an interior configured to receive the solid or liquid feedstock, said interior sized to receive a predetermined amount of inert gas;
an inlet configured to receive the inert gas;
at least one outlet, wherein said inlet and said at least one outlet are sealable such that a static environment is formed in said interior when reacting the solid or liquid feedstock; and
a door configured to provide access to said interior.

10. The reactor in accordance with claim 9, wherein said reactor further comprises a circulating device coupled within said interior, said circulating device configured to circulate the vaporized feedstock throughout said interior.

11. The reactor in accordance with claim 9 further comprising a feedstock holder positioned within said interior, said feedstock holder configured to receive the solid or liquid feedstock.

12. The reactor in accordance with claim 11, wherein said feedstock holder comprises:
a mounting base coupled within said interior; and
a removable receptacle selectively coupled to said mounting base, said removable receptacle configured to receive the solid or liquid feedstock.

13. The reactor in accordance with claim 11 further comprising an electrical discharge device coupled to said feedstock holder, said electrical discharge device comprising a pair of electrodes positioned such that an electrical discharge formed between said pair of electrodes facilitates vaporization of the solid or liquid feedstock.

14. A method of forming carbon nanotubes from solid or liquid feedstock within a reactor, said method comprising:
filling the reactor with a predetermined amount of inert gas;
sealing the reactor such that a static environment is formed within the reactor; and
heating the reactor to a temperature such that the solid or liquid feedstock is vaporized, thereby forming vaporized feedstock.

15. The method in accordance with claim 14 further comprising circulating the vaporized feedstock throughout the reactor such that the vaporized feedstock mixes with the inert gas.

16. The method in accordance with claim 15, wherein circulating the vaporized feedstock comprises actuating at least one circulating device when the temperature within the reactor is greater than a predetermined threshold.

17. The method in accordance with claim 14 further comprising forming an electrical discharge across a pair of electrodes positioned such that the electrical discharge facilitates vaporization of the solid or liquid feedstock.

18. The method in accordance with claim 14 further comprising channeling a stream of neutralizing gas into the reactor after the carbon nanotubes have been formed, wherein the neutralizing gas neutralizes unreacted hydrocarbons of the vaporized feedstock.

19. The method in accordance with claim 14, wherein heating the reactor comprises heating the reactor to the temperature defined within a range between about 800° C. and about 900° C.

20. The method in accordance with claim 14, wherein filling the reactor with a predetermined amount of inert gas comprises:
reducing a pressure within the reactor to a predetermined pressure; and
filling the reactor with the inert gas when a pressure within the reactor reaches the predetermined pressure.
